(19) United States
(12) Patent Application Publication
(10) Pub. No.: US 2018/0035532 A1
(43) Pub. Date: Feb. 1, 2018

(54) Electronic Terminal

(71) Applicant: Wuhan China Star Optoelectronics Technology Co., Ltd., Wuhan, Hubei (CN)

(72) Inventor: Gui CHEN, Shenzhen, Guangdong (CN)

(73) Assignee: Wuhan China Star Optoelectronics Technology Co., Ltd., Wuhan, Hubei (CN)

(21) Appl. No.: 14/914,156

(22) PCT Filed: Feb. 1, 2016
(86) PCT No.: PCT/CN2016/073030

§ 371 Date: Feb. 24, 2016

(30) Foreign Application Priority Data
Dec. 31, 2015 (CN) 201511027947.2

(51) Int. Cl. H05K 1/02; H05K 5/00

(52) U.S. Cl. CPC H05K 1/028; H05K 5/0017; H05K 1/0213

(57) ABSTRACT

An electronic terminal includes a display panel, a printed circuit board and a flexible printed circuit board. A portion of the flexible printed circuit board is located below the printed circuit board, a terminal of the flexible printed circuit board is connected with the display panel, and the other terminal is connected with a port of a driving circuit of the printed circuit board. At a location of a ground wire disposed inside an overlapping region of the flexible printed circuit board and the printed circuit board and disposed on the flexible printed circuit board, a first copper-exposed region is provided. At a location of a ground wire inside the overlapping region and on the printed circuit board, a second copper-exposed region is provided. A length of the ground wire in the printed circuit board is matched with a length of an antenna in the electronic terminal.

### BACKGROUND OF THE INVENTION

### 1. Field of the Invention

The present invention relates to a manufacturing field of an electronic terminal, and more particularly to an electronic terminal which uses a ground wire of a flexible printed circuit board as an extension ground of a ground wire of a printed circuit board.

### 2. Description of Related Art

Currently, along with the development of the electronic science technology, the manufacturing of the electronic terminal is gradually developed toward a light and thin design. In the current technology, to make the electronic terminal to be thinner, a printed circuit board (PCB board) in the electronic terminal is usually reduced.

Generally, reducing the size of the printed circuit board is achieved by reducing a width of the printed circuit board such that when reducing a thickness of the electronic terminal, a waste of combining printed circuit boards can be reduced to save the cost. However, after the width of the printed circuit becomes narrow, a length of the ground wire in the printed circuit board is shorten, and is not matched with the length of the antenna in the electronic terminal. Usually, a copper foil is added in the electronic terminal to be an extension ground of the ground wire in the printed circuit board. However, the development cost of the electronic terminal is increased.

### SUMMARY OF THE INVENTION

The embodiment of the present disclosure is to provide an electronic terminal, without disposing the copper foil, the technology problem that the length of the ground wire of the printed circuit board in the electronic terminal is not matched with the length of the antenna.

According to an embodiment of the present disclosure, the present disclosure provides an electronic terminal comprising a display panel, a printed circuit board and a flexible printed circuit board, wherein a portion of the flexible printed circuit board is located below the printed circuit board, a terminal of the flexible printed circuit board is connected with the display panel, the other terminal of the flexible printed circuit board is connected with a port of a driving circuit of the printed circuit board in order to provide a driving signal for the display panel through the flexible printed circuit board; wherein, at a location of a ground wire of the flexible printed circuit board disposed inside an overlapping region of the flexible printed circuit board and the printed circuit board and disposed on the flexible printed circuit board, a first copper-exposed region is provided; at a location of a ground wire of the printed circuit board disposed inside the overlapping region of the flexible printed circuit board and the printed circuit board and disposed on the printed circuit board, a second copper-exposed region is provided such that the ground wire of the printed circuit board is electronically connected with the ground wire of the flexible printed circuit board.

Optionally, the ground wire of the flexible printed circuit board disposed inside an overlapping region of the flexible printed circuit board and the printed circuit board and disposed on the flexible printed circuit board is a copper-clad region of the flexible printed circuit board; the ground wire of the printed circuit board disposed inside the overlapping region of the flexible printed circuit board and the printed circuit board and disposed on the printed circuit board is a copper-clad region of the printed circuit board.

Optionally, the first copper-exposed region is disposed at a side of the flexible printed circuit board close to the printed circuit board and inside the overlapping portion of the printed circuit board and the flexible printed circuit board; the second copper-exposed region is disposed at a side of the printed circuit board close to the flexible printed circuit board and inside the overlapping portion of the printed circuit board and the flexible printed circuit board.

Optionally, the electronic terminal further comprises a conductive material, and the conductive material is disposed between the first copper-exposed region and the second copper-exposed region such that the copper-clad region of the printed circuit board is electronically connected with the copper-clad region of the flexible circuit board through the conductive material.

Optionally, the conductive material disposed between the first copper-exposed region and the second copper-exposed region is an elastic conductive material.

Optionally, the conductive material is a conductive sponge.

Optionally, the frame of the display panel is made of a non-conductive material.

Optionally, a case of the electronic terminal is made of a non-conductive material.

Optionally, the printed circuit board is an I-shaped board.

Optionally, a length of the flexible printed circuit board is close to a width of the electronic terminal.

The electronic terminal utilizes the ground wire of the flexible circuit board as an extension ground of the ground wire in the printed circuit board such that the ground wire in the printed circuit board is matched with the length of the antenna in the electronic terminal.

### BRIEF DESCRIPTION OF THE DRAWINGS

FIG. 1 is a schematic diagram of a printed circuit board in an electronic terminal according to an embodiment of the present invention; and

FIG. 2 is a schematic diagram of distribution locations of a printed circuit board and a flexible printed circuit board in the electronic terminal according to an embodiment of the present invention.

### DETAILED DESCRIPTION OF THE PREFERRED EMBODIMENT

The following content combines with the drawings and the embodiment for describing the present invention in detail. The example of the embodiment of the present invention is shown in the figures. However, many other forms can be used to implement the present invention. Besides, the present invention should not be interpreted to be limit in the specific embodiment described here. On the contrary, providing these embodiments can make the present disclosure to be thorough and complete, and these embodiments fully transmit the scope of the present disclosure to the person skilled in the art.

For clarity and brevity, the description for unnecessary parts or elements may be omitted. A same numeral in the entire specification and figures represents a same element. In the figures, for clarity, the size and the relative size of layer and region are enlarged, and a distance and a relative distance among elements may be enlarged. Therefore, the figures only schematically show a relative location relationship among the elements, and not limited.

It can also be understood that when a layer or an element is called be to “above” or “on” another element or layer, or called “connected with” another element or layer, the layer or the element can directly form on the another layer or the element or directly connected with another element or layer, or an intermediate layer or an intermediate element can exist. On the contrary, when a layer or an element is called be to “directly above” or “directly on” another element or layer, or called “directly connected with” another element or layer, an intermediate layer or an intermediate element do not exist. The term “and/or” used here includes any combination or all combinations of one or multiple related terms.

It should be noted that although the relational terms such as first and second are used here to describe different elements, components, regions layers and/or parts. However, these elements, components, regions layers and/or parts are not limited by the relational terms. The relational terms are only used to distinguish one element, component, region, layer and/or part from another element, component, region, layer and/or part. Therefore, without leaving the teaching of the present invention, the first element, component, region, layer or part can be named as the second element, component, region, layer or part.

The space relational terms here such as “below”, “located under”, “above”, are used to describe a relationship between one element or feature and another element or feature. It can be noted that the space relational terms are used to include the direction of the device described in the figures and different directions of the device when the device under using or operation. For example, when the device in the figure is reversed, the terms “below”, “located under”, “above” element or feature will subsequently become “above”, “located below”, “below” element or feature. Therefore, the relational term “below” can include two directions of “above” and “below”. The device can be located additionally (rotate 90 degrees or other directions), and correspondingly be explained the space relational terms.

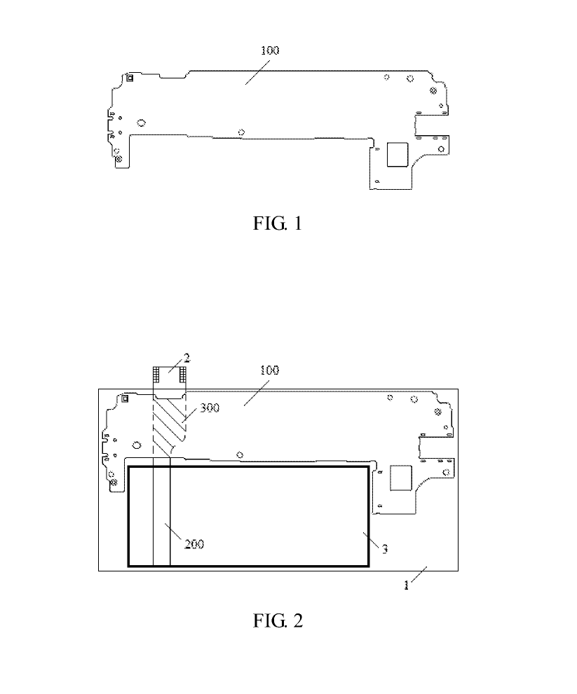

The embodiment of the present disclosure provides an electronic terminal. A printed circuit board 100 in the electronic terminal has a shape as shown in FIG. 1. Preferably, the printed circuit board in the electronic terminal is an I-shaped board. A width of the printed circuit board which is I-shaped is narrower such that a length of a ground line in the printed circuit board is not matched with a length of an antenna in the electronic terminal. Besides, a case of the electronic terminal is made of a non-conductive material, and a frame of a display panel of the electronic terminal is also made of a non-conductive material. That is, the case of electronic terminal and the frame of the display panel both cannot provide a conductive material for connecting the printed circuit board to the ground.

Accordingly, in the electronic terminal provided by the embodiment of the present disclosure, under the premise that the case of electronic terminal and the frame of the display panel both cannot provide a conductive material for connecting the printed circuit board to the ground and without adding a copper foil in the electronic terminal, the electronic terminal of the present disclosure utilizes a ground wire of a flexible circuit board as an extension ground of the ground wire in the printed circuit board in order to increase the length of the ground wire in the printed circuit board such that the length of the ground wire in the printed circuit board is matched with the length of the antenna in the electronic terminal.

The following content will refer to FIG. 2 to describe a specific way of using the ground wire of the flexible circuit board as an extension ground of the ground wire in the printed circuit board (that is, the ground wire in the flexible circuit board and the ground wire in the printed circuit board are electrically connected).

FIG. 2 is a schematic diagram of distribution locations of a printed circuit board and a flexible printed circuit board in the electronic terminal according to an embodiment of the present invention.

As shown in FIG. 2, the electronic terminal 1 according to the embodiment of the present disclosure includes a display panel (not shown in the figure), a printed circuit board (PCB board) 100 and a flexible printed circuit board (FPC) 200.

Specifically, a portion of the flexible printed circuit board 200 is located below the printed circuit board 100. A shaded region 300 in FIG. 2 is an overlapping portion of the printed circuit board 100 and the flexible printed circuit board 200. A numeral 3 means a region for disposing a battery in the electronic terminal 1, and another portion of the flexible printed circuit board 200 can be disposed in the region for disposing a battery (for example, the another portion of the flexible printed circuit board 200 can be disposed below the battery in the electronic terminal 1). A terminal of the flexible printed circuit board 200 is connected with the display panel (not shown in the figure), the other terminal of the flexible printed circuit board 200 (for example, a connection terminal 2 of the flexible printed circuit board 200 shown in FIG. 2) is connected with a port of a driving circuit of the printed circuit board 100 (FIG. 2 does not show that the connection terminal 2 of the flexible printed circuit board 200 is connected with the port of the driving circuit of the printed circuit board 100) in order to provide a driving signal for the display panel through the flexible printed circuit board 200.

At a location of a ground wire of the flexible printed circuit board 200 disposed inside an overlapping region of the flexible printed circuit board 200 and the printed circuit board 100 and disposed on the flexible printed circuit board 200, a first copper-exposed region is provided at a location of a ground wire of the printed circuit board 100 disposed inside the overlapping region 300 of the flexible printed circuit board 200 and the printed circuit board 100 and disposed on the printed circuit board 100, a second copper-exposed region is provided such that the ground wire of the printed circuit board 100 is electrically connected with the ground wire of the flexible printed circuit board 200.

For example, the first copper-exposed region is disposed on the flexible printed circuit board 200, and the first copper-exposed region is disposed at a side of the flexible printed circuit board 200 close to the printed circuit board 100 and inside the overlapping portion 300 of the printed circuit board 100 and the flexible printed circuit board 200. Correspondingly, the second copper-exposed region is disposed on the printed circuit board 100, and the second copper-exposed region is disposed at a side of the printed circuit board 100 close to the flexible printed circuit board 200 and inside the overlapping portion 300 of the printed circuit board 100 and the flexible printed circuit board 200.

As an example, an insulation layer on a surface of the flexible printed circuit board 200 overlapped with the printed circuit board 100 is removed (that is, inside the overlapping portion 300, the insulation layer at the location of the ground wire of the flexible printed circuit board 200 is removed) in order to uncover the ground wire in the flexible printed circuit board 200 in order to form the first copper-exposed region. Correspondingly, an insulation layer on a surface of the printed circuit board 100 overlapped with the flexible printed circuit board 200 is removed (that is, inside the overlapping portion 300, the insulation layer at the location of the ground wire of the printed circuit board 100 is removed) in order to uncover the ground wire in the printed circuit board 100 in order to form the second copper-exposed region.

Here, the ground wire of the flexible printed circuit board inside the overlapping portion of the flexible printed circuit board and the printed circuit board and disposed on the flexible printed circuit board can mean a copper-clad region of the flexible printed circuit board. The ground wire of the printed circuit board inside the overlapping portion of the flexible printed circuit board and the printed circuit board can mean a copper-clad region of the printed circuit board. That is, an insulation layer at a location of the copper-clad region of the flexible printed circuit board 200 inside the overlapping portion of the flexible printed circuit board 200 and the printed circuit board 100 is removed in order to uncover the copper-clad region of the flexible printed circuit board 200 to form the first copper-exposed region. Correspondingly, an insulation layer at a location of the copper-clad region of the printed circuit board 100 inside the overlapping portion of the flexible printed circuit board 200 and the printed circuit board 100 is removed in order to uncover the copper-clad region of the printed circuit board 100 to form the second copper-exposed region.

Optionally, the electronic terminal according to an embodiment of the present disclosure also includes a conductive material, and the conductive material is disposed between the first copper-exposed region and the second copper-exposed region such that the copper-clad region of the printed circuit board 100 is electrically connected with the copper-clad region of the flexible circuit board 200 through the conductive material.

As an example, the conductive material disposed between the first copper-exposed region and the second copper-exposed region is an elastic conductive material. The elastic conductive material can provide a good conductivity and contact such as a conductive sponge so that the copper-clad region of the printed circuit board 100 is electrically connected with the copper-clad region of the flexible printed circuit board 200 through the conductive sponge.

From the embodiment shown in FIG. 2, the length of the flexible printed circuit board 200 is close to the width of the electronic terminal 1 (for example, a difference between the length of the flexible printed circuit board 200 and the width of the electronic terminal 1 is within a predetermined range). Accordingly, after the copper-clad region of the flexible printed circuit board 200 is electrically connected with the copper-clad region of the printed circuit board 100, the length of the ground wire in the printed circuit board 100 is increased. At this time, the length of the ground wire of the printed circuit board 100 is close to ¼ high frequency wavelength of the antenna in the electronic terminal 1 (for example, a difference between the length of the ground wire of the printed circuit board 100 and ¼ high frequency wavelength is within a predetermined range).

From following table 1 and table 2, when the electronic terminal 1 does not add the extension ground of the printed circuit board 100 and does not use the ground wire of the flexible printed circuit board 200 as the extension ground of the ground wire of the printed circuit board 100, a comparison relationship of a passive efficiency of the antenna in the electronic terminal 1 is shown:

TABLE 1

| Frequency | Efficiency (average value) |
|---|---|
| 820~960 | 40.2% |
| 1710~2170 | 18.1% |

TABLE 2

| Frequency | Efficiency (average value) |
|---|---|
| 820~960 | 39.4% |
| 1710~2170 | 42.1% |

Here, the table 1 shows that when the electronic terminal 1 does not add the extension ground of the printed circuit board 100 (that is, does not add a copper foil), the passive efficiency of a low frequency signal and a high frequency signal of the antenna in the electronic terminal 1, and the table 2 shows that when electronic terminal 1 uses the ground wire of the flexible printed circuit board 200 as the extension ground of the ground wire of the printed circuit board 100, the passive efficiency of a low frequency signal and a high frequency signal of the antenna in the electronic terminal 1. From table 1 and table 2, when the copper-clad region of the flexible printed circuit board 200 in the electronic terminal 1 is electrically connected with the printed circuit board 100, the passive efficiency of the high frequency signal of the antenna in the electronic terminal 1 is effectively increased.

The electronic terminal according to the embodiment of the present disclosure utilizes the ground wire of the flexible circuit board as an extension ground of the ground wire in the printed circuit board such that the ground wire in the printed circuit board is matched with the length of the antenna in the electronic terminal. That is, the length of the ground wire in the printed circuit board is approximately equal to the length of the antenna in the electronic terminal (mean that the difference between the length of the ground wire in the printed circuit board and the length of the antenna in the electronic terminal is less than a preset threshold.

The electronic terminal according to the embodiment of the present disclosure utilizes the ground wire of the flexible circuit board as an extension ground of the ground wire in the printed circuit board such that the ground wire in the printed circuit board is matched with the length of the antenna in the electronic terminal. That is, the length of the ground wire in the printed circuit board is approximately equal to the length of the antenna in the electronic terminal (mean that the difference between the length of the ground wire in the printed circuit board and the length of the antenna in the electronic terminal is less than a preset threshold.

The above content combines the embodiments to describe the present invention, however, the implement of the present invention is not limited. Within the spirit and scope of present invention, the person in this technology field can perform various modifications and variations. The modifications and variations are still covered by the claims in the present invention.

What is claimed is:

1. An electronic terminal comprising a display panel, a printed circuit board and a flexible printed circuit board, wherein a portion of the flexible printed circuit board is located below the printed circuit board, a terminal of the flexible printed circuit board is connected with the display panel, the other terminal of the flexible printed circuit board is connected with a port of a driving circuit of the printed circuit board in order to provide a driving signal for the display panel through the flexible printed circuit board;
wherein, at a location of a ground wire of the flexible printed circuit board disposed inside an overlapping region of the flexible printed circuit board and the printed circuit board and disposed on the flexible printed circuit board, a first copper-exposed region is provided; at a location of a ground wire of the printed circuit board disposed inside the overlapping region of the flexible printed circuit board and the printed circuit board and disposed on the printed circuit board, a second copper-exposed region is provided such that the ground wire of the printed circuit board is electrically connected with the ground wire of the flexible printed circuit board.

2. The electronic terminal according to claim 1, wherein, the ground wire of the flexible printed circuit board disposed inside an overlapping region of the flexible printed circuit board and the printed circuit board and disposed on the flexible printed circuit board is a copper-clad region of the flexible printed circuit board; the ground wire of the printed circuit board disposed inside the overlapping region of the flexible printed circuit board and the printed circuit board and disposed on the printed circuit board is a copper-clad region of the printed circuit board.

3. The electronic terminal according to claim 2, wherein, the first copper-exposed region is disposed at a side of the flexible printed circuit board close to the printed circuit board and inside the overlapping portion of the printed circuit board and the flexible printed circuit board; the second copper-exposed region is disposed at a side of the printed circuit board close to the flexible printed circuit board and inside the overlapping portion of the printed circuit board and the flexible printed circuit board.

4. The electronic terminal according to claim 3, wherein, the electronic terminal further comprises a conductive material, and the conductive material is disposed between the first copper-exposed region and the second copper-exposed region such that the copper-clad region of the printed circuit board is electrically connected with the copper-clad region of the flexible circuit board through the conductive material.

5. The electronic terminal according to claim 4, wherein, the conductive material disposed between the first copper-exposed region and the second copper-exposed region is an elastic conductive material.

6. The electronic terminal according to claim 5, wherein, the conductive material is a conductive sponge.

7. The electronic terminal according to claim 1, wherein, the frame of the display panel is made of a non-conductive material.

8. The electronic terminal according to claim 1, wherein, a case of the electronic terminal is made of a non-conductive material.

9. The electronic terminal according to claim 8, wherein, the printed circuit board is an I-shaped board.

10. The electronic terminal according to claim 1, wherein, a length of the flexible printed circuit board is close to a width of the electronic terminal.
